(19) United States
(12) Patent Application Publication
(10) Pub. No.: US 2025/0347751 A1
(43) Pub. Date: Nov. 13, 2025

(54) BATTERY SOH ESTIMATING APPARATUS AND METHOD

(71) Applicant: LG ENERGY SOLUTION, LTD., Seoul (KR)

(72) Inventors: Ji-Hoon JANG, Daejeon (KR); Soo-Bin SONG, Daejeon (KR); Gyu-Yeol LEE, Daejeon (KR); Hyun HAN, Daejeon (KR)

(73) Assignee: LG ENERGY SOLUTION, LTD., Seoul (KR)

(21) Appl. No.: 18/864,786

(22) PCT Filed: May 16, 2023
(86) PCT No.: PCT/KR2023/006640

§ 371 Date: Nov. 11, 2024

(30) Foreign Application Priority Data
May 18, 2022 (KR) 10-2022-0060635

(51) Int. Cl. G01R 31/392; G01R 31/367

(52) U.S. Cl. CPC G01R 31/392; G01R 31/367

(57) ABSTRACT

The present disclosure relates to a battery SOH estimating apparatus and method capable of more accurately estimating a SOH (State of health) of a battery. Specifically, the present disclosure provides a battery SOH estimating apparatus and method that may more accurately estimate the SOH of a battery by correcting the estimated SOH of the battery based on a SOC (State of charge) change amount, a SOC change region, and a temperature of the battery.

### TECHNICAL FIELD

The present application claims priority to Korean Patent Application No. 10-2022-0060635 filed on May 18, 2022, in the Republic of Korea, the disclosures of which are incorporated herein by reference.

The present disclosure relates to a battery SOH estimating apparatus and method, and more particularly, to a battery SOH estimating apparatus and method capable of more accurately estimating a SOH (State of health) of a battery.

### BACKGROUND ART

Recently, the demand for portable electronic products such as notebook computers, video cameras and portable telephones has increased sharply, and electric vehicles, energy storage batteries, robots, satellites, and the like have been developed in earnest. Accordingly, high-performance batteries allowing repeated charging and discharging are being actively studied.

Batteries commercially available at present include nickel-cadmium batteries, nickel hydrogen batteries, nickel-zinc batteries, lithium batteries and the like. Among them, the lithium batteries are in the limelight since they have almost no memory effect compared to nickel-based batteries and also have very low self-discharging rate and high energy density.

The battery capacity of such a battery decreases depending on the usage environment, usage period, the number of times of charging and discharging, etc. The state of health (SOH) of a battery is an index indicating how much the battery capacity has decreased from the initial battery capacity, and is one of the important parameters for evaluating the lifespan of a battery.

In general, the ampere counting method may be used to estimate the SOH of the battery. The ampere counting method is a method of estimating the SOH of a battery by measuring the battery capacity by the ampere counting method through full charge and full discharge, and comparing it with the initial battery capacity. This method may estimate the SOH of the battery very accurately if the variation of temperature or discharging rate may be properly compensated for, but it is not efficient because the battery must be fully charged and then fully discharged. In addition, when the offset is changed due to deterioration of a current sensor that measures the current of the battery, errors are accumulated during the ampere counting process, so the estimation result may be inaccurate.

### DISCLOSURE

### Technical Objectives

The present disclosure is designed to solve the problems of the related art, and therefore a technical object of the present disclosure is to provide a battery SOH estimating apparatus and method that may more accurately estimate the SOH of a battery by correcting the estimated SOH of the battery based on a SOC (State of charge) change amount, a SOC change region, and a temperature of the battery.

These and other objects and advantages of the present disclosure may be understood from the following detailed description and will become more fully apparent from the example embodiments of the present disclosure. Also, it will be easily understood that the objects and advantages of the present disclosure may be realized by the means shown in the appended claims and combinations thereof.

### Technical Solutions

A battery SOH estimating apparatus according to one aspect of the present disclosure may comprise a SOH estimating unit configured to estimate a first SOH of a battery based on battery information including at least one of voltage, current and temperature of the battery; a C-rate calculating unit configured to calculate a charging and discharging C-rate for the battery based on the battery information; a SOC change calculating unit configured to calculate a SOC change region and a SOC change amount of the battery based on the battery information; a weight calculating unit configured to calculate a weight based on at least one of a C-rate factor based on the charging and discharging C-rate, a SOC region factor according to the comparison result between the SOC change region and a preset criterion SOC region, a SOC change amount factor based on the SOC change amount, and a temperature factor based on the temperature of the battery; and a SOH correcting unit configured to correct the first SOH according to the calculated weight and a preset second SOH.

The weight calculating unit may be configured to calculate the C-rate factor corresponding to the calculated charging and discharging C-rate based on a C-rate factor table preset to represent the corresponding relationship between the charging and discharging C-rate and the C-rate factor.

The weight calculating unit may be configured to calculate the C-rate factor corresponding to the calculated C-rate and the temperature based on a C-rate factor table preset to represent the C-rate factor according to the temperature of the battery and the charging and discharging C-rate.

The C-rate factor may be configured to be proportional to the temperature and the C-rate.

The weight calculating unit may be configured to calculate the SOC region factor depending on whether at least a part of the SOC change region belongs to the criterion SOC region.

The criterion SOC region may be provided in plurality.

The weight calculating unit may be configured to calculate the number of SOC regions that include at least a part of the SOC change region among the criterion SOC regions, and calculate the SOC region factor corresponding to the calculated number of SOC regions based on a preset SOC region factor table.

The weight calculating unit may be configured to calculate the SOC change amount factor corresponding to the calculated SOC change amount based on a preset SOC change amount factor table.

The weight calculating unit may be configured to calculate the temperature factor corresponding to the temperature of the battery based on a preset temperature factor table.

The weight calculating unit may be configured to calculate the weight by multiplying the C-rate factor, the SOC region factor, the SOC change amount factor, and the temperature factor.

The SOH estimating unit may be configured to estimate the first SOH in a present cycle based on the battery information in the present cycle.

The SOH estimating unit may be configured to correct the first SOH according to the weight and the second SOH preset prior to the present cycle.

The second SOH may be the first SOH corrected in a previous cycle of the present cycle.

The SOH correcting unit may be configured to correct the first SOH using the following equation.

$$S O {H}_{MOD} = ( S O {H}_{1} \times α ) + ( S O {H}_{2} \times ( 1 - α ) ) \qquad [ Equation ]$$

Here, SOH_{MOD} is the corrected first SOH, SOH₁ is the first SOH, SOH₂ is the second SOH, and α is the weight that is 0 or more and 1 or less.

A battery pack according to another aspect of the present disclosure may comprise the battery SOH estimating apparatus according to an aspect of the present disclosure.

A vehicle according to still another aspect of the present disclosure may comprise the battery SOH estimating apparatus according to an aspect of the present disclosure.

A battery SOH estimating method according to another aspect of the present disclosure may comprise: a SOH estimating step of estimating a first SOH of a battery based on battery information including at least one of voltage, current and temperature of the battery; a C-rate calculating step of calculating a charging and discharging C-rate for the battery based on the battery information; a SOC change calculating step of calculating a SOC change region and a SOC change amount of the battery based on the battery information; a weight calculating step of calculating a weight based on at least one of a C-rate factor based on the charging and discharging C-rate, a SOC region factor according to the comparison result between the SOC change region and a preset criterion SOC region, a SOC change amount factor based on the SOC change amount, and a temperature factor based on the temperature of the battery; and a SOH correcting step of correcting the first SOH according to the calculated weight and a preset second SOH.

### Advantageous Effects

According to one aspect of the present disclosure, the SOH of a battery may be more accurately estimated since various factors for the battery are considered.

The effects of the present disclosure are not limited to the above, and other effects not mentioned herein will be clearly understood by those skilled in the art from the appended claims.

### BRIEF DESCRIPTION OF DRAWINGS

The accompanying drawings illustrate embodiments of the present disclosure and together with the foregoing disclosure, serve to provide further understanding of the technical features of the present disclosure, and thus, the present disclosure is not construed as being limited to the drawing.

FIG. 1 is a diagram schematically showing a battery SOH estimating apparatus according to an embodiment of the present disclosure.

FIG. 2 is a diagram schematically showing the SOH estimating process by the battery SOH estimating apparatus according to an embodiment of the present disclosure.

FIG. 3 is a diagram schematically showing a negative electrode differential profile of the battery.

FIG. 4 is a diagram schematically showing a positive electrode differential profile of the battery.

FIG. 5 is a diagram schematically showing an example of a SOC region factor table set in the battery SOH estimating apparatus according to an embodiment of the present disclosure.

FIG. 6 is a diagram schematically showing an example of a SOC change amount factor table set in the battery SOH estimating apparatus according to an embodiment of the present disclosure.

FIG. 7 is a diagram schematically showing an example of a temperature factor table set in a battery SOH estimating apparatus according to an embodiment of the present disclosure.

FIG. 8 is a diagram schematically showing an example of a C-rate factor table set in the battery SOH estimating apparatus according to an embodiment of the present disclosure.

FIG. 9 is a diagram schematically showing another example of the C-rate factor table set in the battery SOH estimating apparatus according to an embodiment of the present disclosure.

FIG. 10 is a diagram schematically showing an example configuration of a battery pack according to another embodiment of the present disclosure.

FIG. 11 is a diagram schematically showing a battery SOH estimating method according to still another embodiment of the present disclosure.

### MODES FOR PRACTICING THE DISCLOSURE

It should be understood that the terms used in the specification and the appended claims should not be construed as limited to general and dictionary meanings, but should be interpreted based on the meanings and concepts corresponding to technical aspects of the present disclosure on the basis of the principle that the inventor is allowed to define terms appropriately for the best explanation.

Therefore, the description proposed herein is just a preferable example for the purpose of illustrations only, not intended to limit the scope of the disclosure, so it should be understood that other equivalents and modifications could be made thereto without departing from the scope of the disclosure.

Additionally, in describing the present disclosure, when it is deemed that a detailed description of relevant known elements or functions renders the key subject matter of the present disclosure ambiguous, the detailed description is omitted herein.

The terms including the ordinal number such as “first”, “second” and the like, may be used to distinguish one element from another among various elements, but not intended to limit the elements by the terms.

Throughout the specification, when a portion is referred to as “comprising” or “including” any element, it means that the portion may include other elements further, without excluding other elements, unless specifically stated otherwise.

In addition, throughout the specification, when a portion is referred to as being “connected” to another portion, it is not limited to the case that they are “directly connected”, but it also includes the case where they are “indirectly connected” with another element being interposed between them.

Hereinafter, a preferred embodiment of the present disclosure will be described in detail with reference to the accompanying drawings.

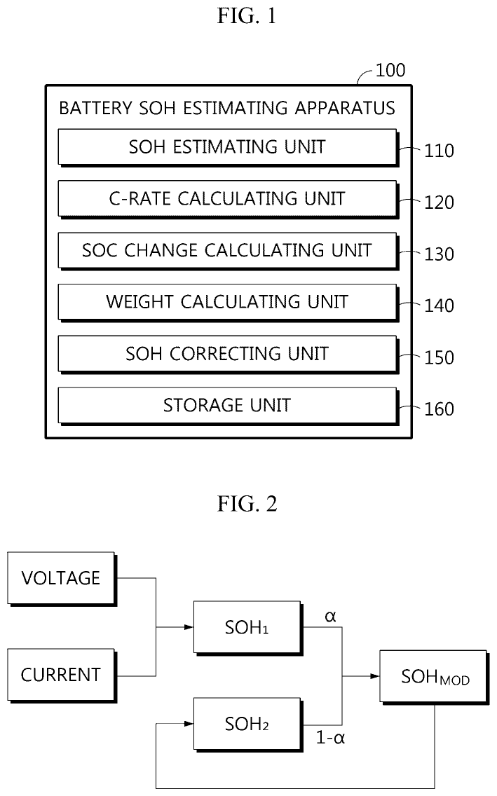

FIG. 1 is a diagram schematically showing a battery SOH estimating apparatus 100 according to an embodiment of the present disclosure.

Here, the battery refers to one physically separable independent cell having a negative electrode terminal and a positive electrode terminal. For example, a lithium-ion battery or a lithium polymer cell may be regarded as the battery. In addition, the battery may refer to a battery module in which a plurality of cells are connected in series and/or in parallel. Hereinafter, for convenience of description, the battery will be described as meaning one independent cell.

With reference to FIG. 1, the battery SOH estimating apparatus 100 may include a SOH estimating unit 110, a C-rate calculating unit 120, a SOC change calculating unit 130, a weight calculating unit 140 and a SOH correcting unit 150.

The SOH estimating unit 110 may be configured to estimate a first SOH of a battery based on battery information including at least one of voltage, current and temperature of the battery.

For example, the SOH estimating unit 110 may receive battery information including at least one of voltage, current, and temperature of the battery from the outside or may store the battery information in advance. Preferably, the SOH estimating unit 110 may estimate the SOH based on battery information including all of voltage, current, and temperature of the battery.

As another example, the SOH estimating unit 110 may be configured to directly measure the voltage, current, and temperature of the battery.

Specifically, the SOH estimating unit 110 may be configured to estimate the first SOH in a present cycle based on the battery information in the present cycle.

For example, the SOH estimating unit 110 may estimate the first SOH of the battery based on the change in capacity of the battery. The SOH estimating unit 110 may estimate a corresponding state of charge (SOC) from the voltage of the battery.

Here, an SOC profile representing a corresponding relationship between the voltage of the battery and the SOC may be preset, and the SOH estimating unit 110 may estimate the corresponding SOC from the voltage of the battery based on the SOC profile. Alternatively, the SOC profile may be preset to represent a corresponding relationship among the voltage, temperature, and SOC of the battery. In this case, the SOH estimating unit 110 may estimate the SOC corresponding to the voltage and temperature of the battery based on the SOC profile.

In addition, the SOH estimating unit 110 may calculate the capacity of the battery based on the estimated SOC and the battery current. Thereafter, the SOH estimating unit 110 may estimate the first SOH of the battery by calculating a ratio between a preset criterion capacity and the calculated capacity for the battery. Here, the criterion capacity is a preset value of the capacity of a battery in a BOL (Beginning of life) state, and may be a capacity value corresponding to the OCV of the battery calculated by the SOH estimating unit 110.

As another example, the SOH estimating unit 110 may estimate the first SOH of the battery based on the change in internal resistance of the battery. The SOH estimating unit 110 may estimate the internal resistance of the battery from the voltage and current of the battery based on Ohm's law. In addition, the SOH estimating unit 110 may estimate the first SOH of the battery by calculating a ratio between a preset criterion resistance and the calculated internal resistance for the battery. Here, the criterion resistance may be a preset value of the internal resistance of a battery in a BOL state.

The first SOH of the battery estimated by the SOH estimating unit 110 may be an SOH value based on the voltage and current of the battery measured in the present cycle.

The C-rate calculating unit 120 may be configured to calculate the charging and discharging C-rate for the battery based on the battery information. Here, C-rate may be an indicator representing the charge/discharge rate.

For example, the C-rate calculating unit 120 may receive information about the current flowing through the charging and discharging path (e.g., large current path) of the battery from the outside. Also, the C-rate calculating unit 120 may calculate the C-rate from the information about the current flowing through the charging and discharging path. Here, the information about the battery current obtained by the C-rate calculating unit 120 may be the same as the information about the battery current obtained by the SOH estimating unit 110.

As another example, the C-rate calculating unit 120 may directly measure the charging and discharging current of the battery and calculate the C-rate based on the measured charging and discharging current.

The SOC change calculating unit 130 may be configured to calculate the SOC change region and the SOC change amount of the battery based on the battery information.

For example, the SOC change calculating unit 130 may be configured to calculate the SOC change region and the SOC change amount of the battery based on the voltage of the battery.

Specifically, the measured battery voltage may be plural. Preferably, the voltage of the battery may be measured during charging and/or discharging, and may include a start voltage and an end voltage. In addition, the SOC change calculating unit 130 may estimate the SOC for the measured voltage (start voltage and end voltage) with reference to the SOC profile. The SOC change calculating unit 130 may calculate an SOC change region including the estimated SOC. Also, the SOC change calculating unit 130 may calculate the SOC change amount by calculating a difference between the estimated SOCs.

For example, it is assumed that the measured battery voltages are V1 and V2, and the battery is charged from voltage V1 to voltage V2. The SOC change calculating unit 130 may estimate SOC1 corresponding to the voltage V1 and SOC2 corresponding to the voltage V2, respectively. The SOC change calculating unit 130 may calculate the SOC change region including SOC1 and SOC2 by setting the start SOC and the end SOC of the SOC change region to SOC1 and SOC2, respectively.

Also, the SOC change calculating unit 130 may calculate the SOC change amount by calculating the formula of “|SOC2−SOC1|”. That is, the SOC change calculating unit 130 may calculate the SOC change amount by calculating an absolute value of the SOC deviation of SOC2 and SOC1. Here, the SOC change amount may be expressed as ΔSOC, and may be calculated as a value of 0% or more and 100% or less.

The weight calculating unit 140 may be configured to calculate the weight based on at least one of a C-rate factor based on the charging and discharging C-rate, a SOC region factor according to the comparison result between the SOC change region and a preset criterion SOC region, a SOC change amount factor based on the SOC change amount, and a temperature factor based on the measured temperature of the battery.

In addition, the weight calculating unit 140 may be configured to calculate the C-rate factor, the SOC region factor, the SOC change amount factor, and the temperature factor, respectively.

For example, the weight calculating unit 140 may receive the temperature of the battery from the outside or store the same in advance. Alternatively, the weight calculating unit 140 may be configured to directly measure the temperature of the battery.

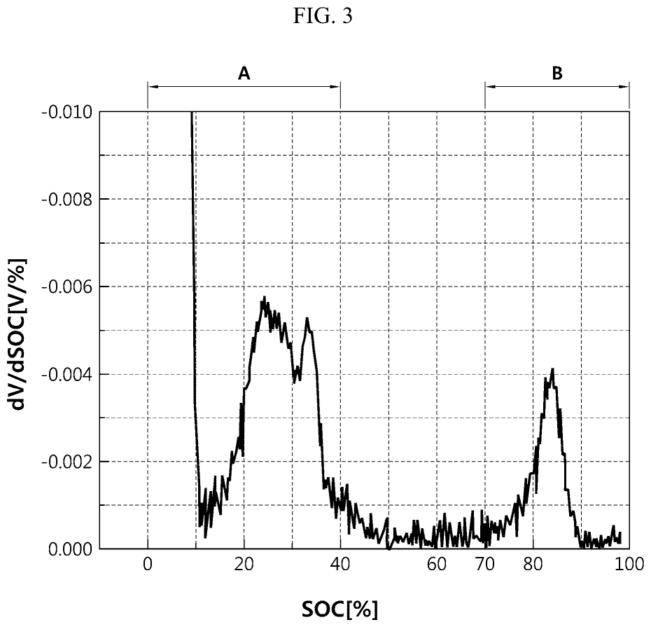

The SOC region factor may be calculated according to whether the preset criterion SOC region and the SOC change region calculated by the SOC change calculating unit 130 overlap. For example, the weight calculating unit may calculate the SOC region factor according to whether at least a part of the SOC change region belongs to the criterion SOC region. A specific embodiment of calculating the SOC region factor will be described later in detail with reference to FIGS. 3 to 5.

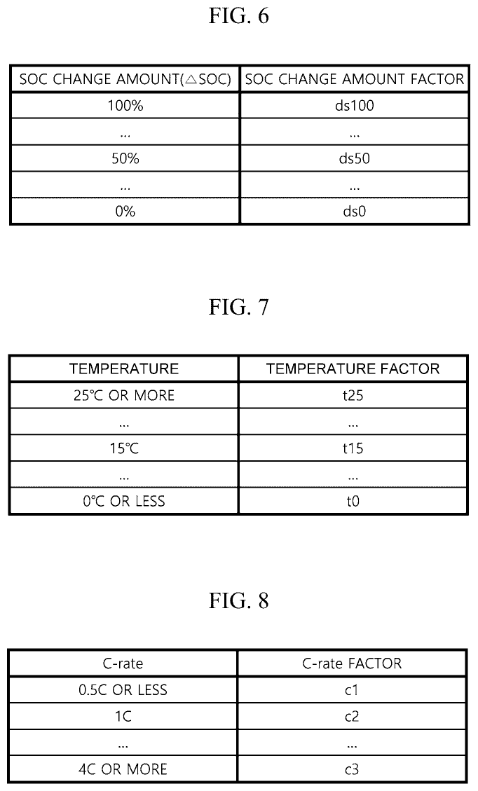

The SOC change amount factor is a factor calculated based on the SOC change amount calculated by the SOC change calculating unit 130. For example, the weight calculating unit 140 may calculate the SOC change amount factor to be proportional to the SOC change amount. A specific embodiment of calculating the SOC change amount factor will be described in detail later with reference to FIG. 6.

The temperature factor is a factor calculated based on the temperature of the battery. For example, the weight calculating unit 140 may calculate the temperature factor to be proportional to the temperature of the battery. A specific embodiment of calculating the temperature factor will be described later in detail with reference to FIG. 7.

The C-rate factor is a factor calculated based on the C-rate calculated by the C-rate calculating unit 120. For example, the weight calculating unit 140 may calculate the C-rate factor to be proportional to the calculated C-rate. A specific example in which the C-rate factor is calculated will be described in detail later with reference to FIG. 8.

Also, the weight calculating unit 140 may be configured to calculate a weight based on the C-rate factor, the SOC region factor, the SOC change amount factor, and the temperature factor. For example, the weight calculating unit 140 may be configured to calculate the weight by multiplying the C-rate factor, the SOC region factor, the SOC change amount factor, and the temperature factor. Here, the weight calculated by the weight calculating unit 140 may be set to have a value of 0 or more and 1 or less.

The SOH correcting unit 150 may be configured to correct the first SOH according to the calculated weight and a preset second SOH.

Specifically, the SOH correcting unit 150 may be configured to correct the first SOH according to the weight and a second SOH set before the present cycle. That is, the first SOH estimated by the SOH estimating unit 110 based on the battery information may be corrected by the SOH correcting unit 150 based on the weight and the second SOH.

FIG. 2 is a diagram schematically showing the SOH estimating process by the battery SOH estimating apparatus 100 according to an embodiment of the present disclosure.

With reference to FIG. 2, the first SOH (SOH₁) may be estimated based on the voltage and current of the battery. In addition, the first SOH (SOH₁) may be corrected based on the second SOH (SOH₂) and the weight (α), and the corrected first SOH (SOH_{MOD}) may be calculated.

For example, the SOH correcting unit 150 may be configured to correct the first SOH using the following equation.

$$S O {H}_{MOD} = ( S O {H}_{1} \times α ) + ( S O {H}_{2} \times ( 1 - α ) ) \qquad [ Equation ]$$

Here, SOH_{MOD} is the corrected first SOH, SOH₁ is the first SOH, SOH₂ is the second SOH, and α is a weight that may be 0 or more and 1 or less.

In the embodiment according to the above equation, the SOH correcting unit 150 may multiply the first SOH (SOH₁) by the weight (α), and multiply the second SOH (SOH₂) by the complement (1−α) for the weight (α). In addition, the SOH correcting unit 150 may calculate the corrected first SOH (SOH_{MOD}) by adding the first SOH (SOH₁) multiplied by weight (α) and the second SOH (SOH₂) multiplied by the complement (1−α).

With reference to FIG. 2 further, the SOH estimating unit 110 may be configured to estimate the first SOH (SOH₁) in the present cycle based on the battery information (e.g., at least one of voltage, current and temperature) corresponding to the present cycle.

For example, the SOH estimating unit 110 may estimate the first SOH (SOH₁) in the present cycle of the battery based on the battery information. In addition, the SOH correcting unit 150 may be configured to correct the first SOH (SOH₁) according to the weight (α) and the second SOH (SOH₂) preset prior to the present cycle.

Also, with reference to FIG. 2, the second SOH (SOH₂) may be the first SOH (SOH_{MOD}) corrected in the previous cycle of the present cycle. That is, the corrected SOH (SOH_{MOD}) calculated in the present cycle may be used as the second SOH (SOH₂) in the next cycle.

The battery SOH estimating apparatus 100 according to an embodiment of the present disclosure has an advantage of more accurately estimating the battery SOH by considering various factors such as the C-rate, SOC change region, SOC change amount and temperature.

In addition, as the charging and discharging cycle of the battery progresses, the battery SOH estimating apparatus 100 may recursively estimate the SOH of the battery in the present cycle by considering the SOH (second SOH) of the battery estimated in the previous cycle and the weight calculated in the present cycle, and thus has an advantage of improving the SOH estimation accuracy of the battery.

Meanwhile, the SOH estimating unit 110, the C-rate calculating unit 120, the SOC change calculating unit 130, the weight calculating unit 140 and the SOH correcting unit 150 included in the battery SOH estimating apparatus 100 may optionally include an application-specific integrated circuit (ASIC), another chipset, a logic circuit, a register, a communication modem, and a data processing device, and the like, known in the art to execute various control logics disclosed below.

In addition, the battery SOH estimating apparatus 100 may further include a storage unit 160. The storage unit 160 may store data necessary for operation and function of each component of the battery SOH estimating apparatus 100, data generated in the process of performing the operation or function, or the like. The storage unit 160 is not particularly limited in its kind as long as it is a known information storage means that can record, erase, update and read data. As an example, the information storage means may include RAM, flash memory, ROM, EEPROM, registers, and the like. In addition, the storage unit 160 may store program codes in which processes executable by the SOH estimating unit 110, the C-rate calculating unit 120, the SOC change calculating unit 130, the weight calculating unit 140 and the SOH correcting unit 150 are defined.

Hereinafter, an embodiment in which the SOC region factor is calculated based on the SOC change region will be described.

The weight calculating unit 140 may be configured to calculate the SOC region factor according to whether at least a part of the SOC change region belongs to the criterion SOC region.

Preferably, the criterion SOC region may be configured to include a plurality of SOC regions. Accordingly, the weight calculating unit 140 may be configured to calculate the SOC region factor according to whether at least a part of the SOC change region belongs to each of the plurality of SOC regions.

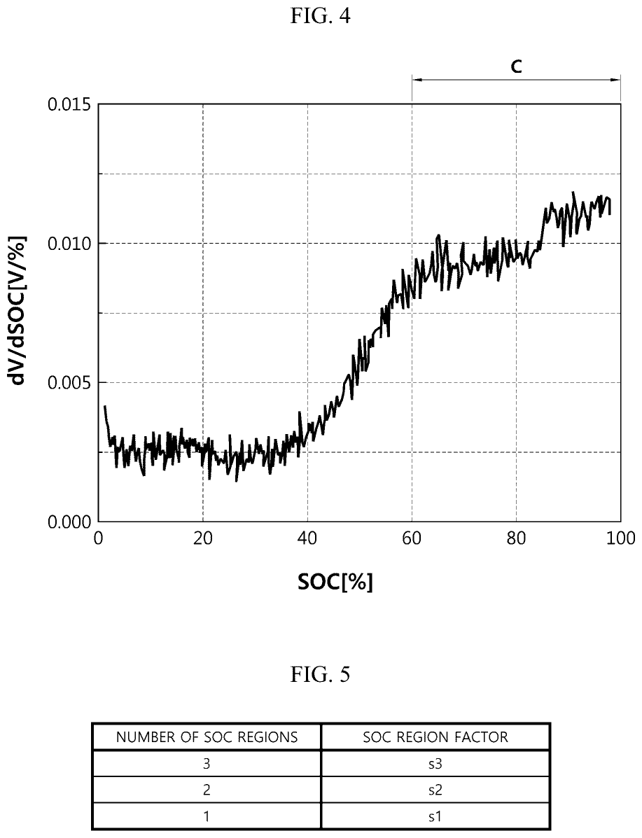

FIG. 3 is a diagram schematically showing a negative electrode differential profile of the battery. FIG. 4 is a diagram schematically showing a positive electrode differential profile of the battery.

The differential profile of FIGS. 3 and 4 is preset for a battery in a BOL state, and may be a differential profile representing a corresponding relationship between a differential voltage (dV/dSOC) for SOC and SOC. Specifically, the differential voltage may be an instantaneous change rate of the voltage (V) with respect to SOC. In addition, the differential profile may be expressed as an X-Y graph when X is SOC and Y is differential voltage (dV/dSOC).

In the negative electrode differential profile of the embodiment of FIG. 3, the intrinsic stress region of the negative electrode active material may appear in the SOC 0% to 40% region and the SOC 70% to 100% region. In addition, in the positive electrode differential profile of the embodiment of FIG. 4, the intrinsic stress region of the positive electrode active material may appear in the SOC 60% to 100% region.

Accordingly, the plurality of criterion SOC regions may be preset for each of the intrinsic stress region of the positive electrode active material and the intrinsic stress region of the negative electrode active material. For example, with reference to FIGS. 3 and 4, the first criterion SOC region A may be set to the SOC 0% to 40% region, the second criterion SOC region B may be set to the SOC 70% to 100% region, and the third criterion SOC region C may be set to the SOC 60% to 100% region.

However, in the embodiments of FIGS. 3 and 4, a total of three criterion SOC regions are set for the battery, but it should be noted that the number and size of the criterion SOC regions may vary according to the change in the active material composition of the battery.

In addition, the weight calculating unit 140 may be configured to calculate the number of criterion SOC regions including at least a part of the SOC change regions among the plurality of SOC regions, and calculate the SOC region factor according to the calculated number.

FIG. 5 is a diagram schematically showing an example of a SOC region factor table set in the battery SOH estimating apparatus 100 according to an embodiment of the present disclosure. The number of criterion SOC regions and the SOC region factor included in the embodiment of FIG. 5 are only examples, and the present disclosure should not be construed as limited by the embodiment of FIG. 5.

Specifically, the SOC region factor table of FIG. 5 may be a look-up table in which the SOC region factor is preset according to the number of criterion SOC regions to which at least a part of the SOC change region of the battery belongs.

For example, the SOC region factor may be set to a value between 0 and 1. Preferably, the SOC region factor can be set to 1 when the SOC change region of the battery is entirely included in the criterion SOC region. Also, the remaining SOC region factors can be set according to the number of criterion SOC regions in which the SOC change region of the battery is included. For example, in the embodiment of FIG. 5, s3, s2, and s1 may be set to 1, 0.66, and 0.33, respectively.

For example, if at least a part of the SOC change region of the battery belongs to all of the first to third criterion SOC regions (A, B, C), the SOC region factor may be s3. For example, when the SOC change region of the battery is the SOC 30% to 80% region, at least a part of the SOC change regions (30% to 80%) of the battery may be all included in the first to third criterion SOC regions (A, B, C). Therefore, the SOC region factor for the battery may be set to s3.

As another example, if at least a part of the SOC change region of the battery belongs to only any two of the first to third criterion SOC regions (A, B, C), the SOC region factor may be s2. For example, when the SOC change region of the battery is the SOC 50% to 80% region, at least a part of the SOC change region (50% to 80%) of the battery may be included in the second and third criterion SOC regions (B, C). Therefore, the SOC region factor for the battery may be set to s2.

As still another example, if at least a part of the SOC change region of the battery belongs to only one of the first to third criterion SOC regions (A, B, C), the SOC region factor may be s1. For example, when the SOC change region of the battery is the SOC 30% to 50% region, at least a part of the SOC change region (30% to 50%) of the battery may be included in the first criterion SOC region (A). Therefore, the SOC region factor for the battery may be set to s1.

However, since the embodiment of FIG. 5 is an embodiment having three preset criterion SOC regions, it should be noted that if the number of preset criterion SOC regions is changed, the SOC region factor may also be changed accordingly. For example, unlike the embodiment of FIG. 5, it is assumed that five criterion SOC regions are set. In this case, the number of SOC regions to which at least a part of the SOC change region belongs may be 5, 4, 3, 2, or 1. The SOC region factor may be preset to s5 (the number of SOC regions belonging thereto is 5), s4 (the number of SOC regions belonging thereto is 4), s3 (the number of SOC regions belonging thereto is 3), s2 (the number of SOC regions belonging thereto is 2), and s1 (the number of SOC regions belonging thereto is 1).

In general, in the course of charging and discharging the battery, the degradation of the battery may be accelerated as the SOC of the battery is included in the intrinsic stress region of the positive electrode active material and/or the intrinsic stress region of the negative electrode active material. Therefore, the battery SOH estimating apparatus 100 according to an embodiment of the present disclosure has an advantage of calculating the SOC region factor in consideration of whether the degradation of the battery is accelerated according to the intrinsic stress region of the active material in order to more accurately estimate the battery SOH.

Hereinafter, an embodiment in which the SOC change amount factor is calculated based on the SOC change amount will be described.

The weight calculating unit 140 may be configured to calculate the SOC change amount factor to be proportional to the SOC change amount.

Specifically, the weight calculating unit 140 may be configured to calculate a SOC change amount factor corresponding to the SOC change amount calculated based on the preset SOC change amount factor table.

Here, the SOC change amount is a difference between the start SOC and the end SOC of the battery in one cycle, and is calculated as “|end SOC−start SOC|”, and may be expressed as ΔSOC. Here “|x|” means an absolute value of x.

FIG. 6 is a diagram schematically showing an example of a SOC change amount factor table set in the battery SOH estimating apparatus 100 according to an embodiment of the present disclosure. The SOC change amount and the SOC change amount factor included in the embodiment of FIG. 6 are only examples, and the present disclosure should not be construed as limited by the embodiment of FIG. 6.

Specifically, the SOC change amount factor table of FIG. 6 may be a look-up table in which the SOC change amount factor is preset according to the SOC change amount of the battery.

Preferably, the SOC change amount factor may be preset to be proportional to the SOC change amount (ΔSOC) of the battery. In the embodiment of FIG. 6, the SOC change amount factor may be a value obtained by converting the SOC change amount (ΔSOC) to have a value of ds0 to ds100. For example, ds0 may correspond to 0, ds50 may correspond to 0.5, and ds100 may correspond to 1.

For example, as in the previous embodiment, it is assumed that the SOC change region of the battery is the SOC 30% to 80% region. In this case, the SOC change amount (ΔSOC) may be 50%. Accordingly, according to the SOC change amount factor table of FIG. 6, the SOC change amount factor for the battery may be set to ds50 (e.g., 0.5).

Hereinafter, an embodiment in which the temperature factor is calculated based on the temperature of the battery will be described.

The weight calculating unit 140 may be configured to calculate the temperature factor according to a region to which the temperature of the battery belongs among a plurality of preset temperature regions.

Specifically, the weight calculating unit 140 may be configured to calculate a temperature factor corresponding to the temperature of the battery based on a preset temperature factor table.

Here, the battery temperature may be an average temperature or a maximum temperature of the battery in one cycle.

FIG. 7 is a diagram schematically showing an example of a temperature factor table set in a battery SOH estimating apparatus 100 according to an embodiment of the present disclosure. The temperature and the temperature factor included in the embodiment of FIG. 7 are merely examples, and the present disclosure should not be construed as limited by the embodiment of FIG. 7.

Specifically, the temperature factor table of FIG. 7 may be a look-up table in which the temperature factor is preset according to the temperature of the battery. In addition, the temperature factor may be preset to be proportional to the temperature of the battery. For example, the temperature factor may be a value obtained by converting the temperature of the battery to have a value of t0 to t25.

For example, when the temperature of the battery is 25° C. or higher, the temperature factor may be set to t25. When the temperature of the battery is 15° C., the temperature factor may be set to t15. When the temperature of the battery is 0° C. or less, the temperature factor may be set to t0.

In addition, the temperature factor for the temperature of the battery not recorded in the temperature factor table may be calculated through the temperature of the battery and the temperature factor included in the temperature factor table. For example, the weight calculating unit 140 may calculate a temperature factor corresponding to a temperature of the battery not included in the temperature factor table by applying a method such as interpolation to the temperature factor table.

For example, in the embodiment of FIG. 7, it is assumed that t0, t15, and t25 are 0, 0.5, and 1, respectively. If the temperature of the battery is 3° C., 6° C., 9° C., 12° C., 18° C., 21° C., and 24° C., which are not included in the temperature factor table, the weight calculating unit 140 may calculate the temperature factor for each temperature as 0.1, 0.2, 0.3, 0.4, 0.8, and 0.95 by using the interpolation method.

Hereinafter, an embodiment in which the C-rate factor is calculated based on the charging and discharging C-rate will be described.

The weight calculating unit 140 may be configured to calculate the C-rate factor corresponding to the calculated charging and discharging C-rate based on a C-rate factor table preset to represent the corresponding relationship between the charging and discharging C-rate and the C-rate factor.

FIG. 8 is a diagram schematically showing an example of a C-rate factor table set in the battery SOH estimating apparatus 100 according to an embodiment of the present disclosure. The C-rate and the C-rate factor included in the embodiment of FIG. 8 are only examples, and the present disclosure should not be construed as limited by the embodiment of FIG. 8.

In the embodiment of FIG. 8, when the C-rate is 0.5 C or less, the C-rate factor may be set to c1. If the C-rate is 0.5 C or more and less than 4 C, the C-rate factor may be set to correspond to each C-rate. If the C-rate is 4 C or more, the C-rate factor may be set to c3. For example, in the embodiment of FIG. 8, the C-rate factor corresponding to 1 C may be set to c2.

As another example, the C-rate factor may be set to correspond to the C-rate region to which the charging and discharging C-rate of the battery belongs. For example, in the embodiment of FIG. 8, when the C-rate is 0.5 C or less, the C-rate factor may be set to c1. If the C-rate is more than 0.5 C and 1 C or less, the C-rate factor may be set to c2. If the C-rate is 4 C or more, the C-rate factor may be set to c3.

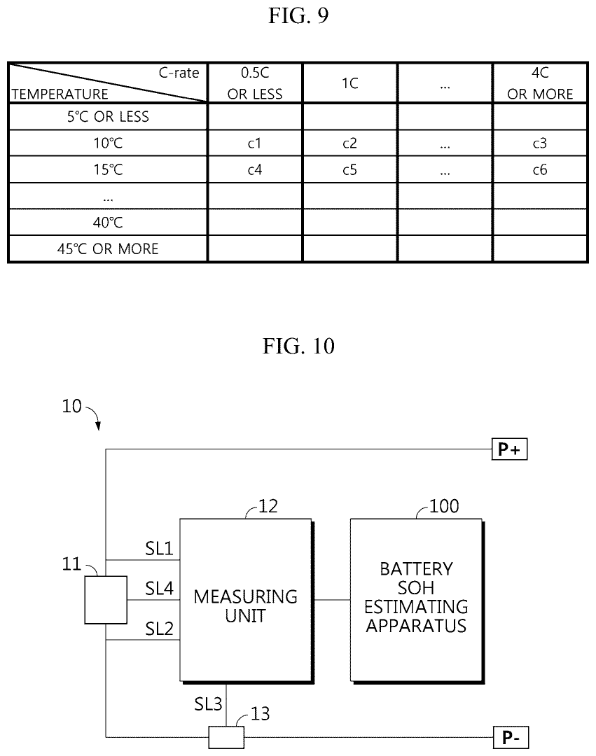

FIG. 9 is a diagram schematically showing another example of the C-rate factor table set in the battery SOH estimating apparatus 100 according to an embodiment of the present disclosure.

The weight calculating unit 140 may be configured to calculate the C-rate factor corresponding to the calculated C-rate and temperature based on a C-rate factor table preset to represent the C-rate factor according to the temperature of the battery and the charging and discharging C-rate.

In other words, the C-rate factor table may be configured to represent the C-rate factor according to the temperature of the battery and the charging and discharging C-rate. Specifically, the C-rate factor may be configured to be proportional to temperature and C-rate.

For example, in the embodiment of FIG. 9, it is assumed that the temperature of the battery is 10° C. When the charging and discharging C-rate is 0.5 C or less, 1 C, and 4 C or more, the C-rate factor may be c1, c2, and c3, respectively. Here, the value of the C-rate factor may increase in the order of c1, c2, and c3.

As another example, in the embodiment of FIG. 9, it is assumed that the temperature of the battery is 15° C. When the charging and discharging C-rate is 0.5 C or less, 1 C, and 4 C or more, the C-rate factor may be c4, c5, and c6, respectively. Here, the value of the C-rate factor may increase in the order of c4, c5, and c6.

Additionally, the value of c4 may be greater than c1, the value of c5 may be greater than c2, and the value of c6 may be greater than c3.

The battery SOH estimating apparatus 100 according to an embodiment of the present disclosure may calculate a weight based on the temperature of the battery, the SOC change amount, the SOC change region, and the charging and discharging C-rate. That is, the battery SOH estimating apparatus 100 has an advantage of more accurately estimating the SOH of the battery by considering various factors (temperature, SOC change amount, SOC change region, and charging and discharging C-rate) affecting the degradation of the battery. In particular, since the battery SOH estimating apparatus 100 considers the SOC change region factor caused by the intrinsic stress region of the active material, it has an advantage of reflecting the degradation acceleration factor of the battery in estimating the SOH of the battery.

The battery SOH estimating apparatus 100 according to the present disclosure may be applied to a battery management system (BMS). That is, the BMS according to the present disclosure may include the battery SOH estimating apparatus 100 described above. In this configuration, at least some of components of the battery SOH estimating apparatus 100 may be implemented by supplementing or adding functions of the components included in a conventional BMS. For example, the SOH estimating unit 110, the C-rate calculating unit 120, the SOC change calculating unit 130, the weight calculating unit 140, the SOH correcting unit 150 and the storage unit 160 of the battery SOH estimating apparatus 100 may be implemented as components of the BMS.

In addition, the battery SOH estimating apparatus 100 according to the present disclosure may be provided to a battery pack. That is, the battery pack according to the present disclosure may include the above-described battery SOH estimating apparatus 100 and one or more battery cells. In addition, the battery pack may further include electrical components (a relay, a fuse and the like) and a case.

FIG. 10 is a diagram schematically showing an example configuration of a battery pack according to another embodiment of the present disclosure.

The positive electrode terminal of the battery 11 may be connected to the positive electrode terminal P+ of the battery pack 10, and the negative electrode terminal of the battery 11 may be connected to the negative electrode terminal P− of the battery pack 10.

The measuring unit 12 may be connected to the first sensing line SL1, the second sensing line SL2, the third sensing line SL3 and the fourth sensing line SL4.

Specifically, the measuring unit 12 may be connected to the positive electrode terminal of the battery 11 through the first sensing line SL1, and may be connected to the negative electrode terminal of the battery 11 through the second sensing line SL2. The measuring unit 12 may measure the voltage of the battery 11 based on the voltage of the battery at each of the first sensing line SL1 and the second sensing line SL2.

In addition, the measuring unit 12 may be connected to the current measuring unit 13 through the third sensing line SL3. For example, the current measuring unit 13 may be an ammeter or a shunt resistor capable of measuring the charging current and the discharging current of the battery 11. The measuring unit 12 may calculate the charge amount by measuring the charging current of the battery 11 through the third sensing line SL3. Also, the measuring unit 12 may calculate the discharge amount by measuring the discharging current of the battery 11 through the third sensing line SL3.

Also, the measuring unit 12 may measure the temperature of the battery 11 through the fourth sensing line SL4.

The voltage, current and temperature of the battery 11 measured by the measuring unit 12 may be transmitted to the battery SOH estimating apparatus 100. The battery SOH estimating apparatus 100 may estimate the SOH of the battery 11 based on the voltage, current, and temperature of the battery 11 received from the measuring unit 12. In addition, the battery SOH estimating apparatus 100 may calculate a charging and discharging C-rate of the battery 11 based the current of the battery 11 received from the measuring unit 12.

Additionally, the battery SOH estimating apparatus 100 according to the present disclosure may be provided in a vehicle. More specifically, the vehicle may be an electric vehicle that receives an operating power through a battery pack. Additionally, the vehicle may include a battery pack including the battery SOH estimating apparatus 100.

For example, in the process of charging and discharging (driving) a vehicle, the battery SOH estimating apparatus 100 has an advantage of estimating the SOH of the battery more accurately by considering various factors (temperature, SOC change amount, SOC change region, and charging and discharging C-rate) that affect deterioration of the battery.

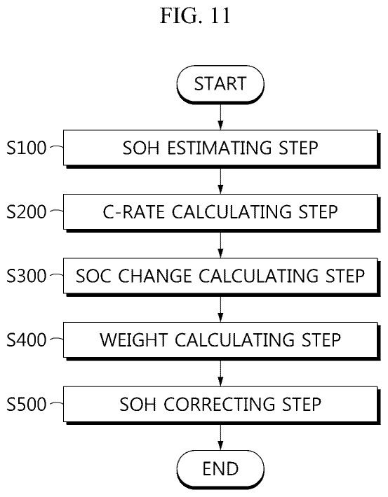

FIG. 11 is a diagram schematically showing a battery SOH estimating method according to still another embodiment of the present disclosure.

Preferably, each step of the battery SOH estimating method may be performed by the battery SOH estimating apparatus 100. Hereinafter, for convenience of explanation, the content overlapping with the previously described content will be omitted or briefly described.

With reference to FIG. 11, the SOH estimation method may include a SOH estimating step (S100), a C-rate calculating step (S200), a SOC change calculating step (S300), a weight calculating step (S400), and a SOH correcting step (S500).

The SOH estimating step (S100) is a step of estimating a first SOH of a battery based on battery information including at least one of voltage, current and temperature of the battery, and may be performed by the SOH estimating unit 110.

The C-rate calculating step (S200) is a step of calculating a charging and discharging C-rate for the battery based on the battery information, and may be performed by the C-rate calculating unit 120.

For example, the C-rate calculating unit 120 may calculate the charging and discharging C-rate of the battery based on information about a current flowing through the charging and discharging path (e.g., large current path) of the battery.

The SOC change calculating step (S300) is a step of calculating a SOC change region and a SOC change amount of the battery based on the voltage of the battery, and may be performed by the SOC change calculating unit 130.

The SOC change calculating unit 130 may calculate the SOC change region and the SOC change amount between the start SOC and the end SOC of the battery in one cycle, respectively.

For example, when the battery is charged from 30% SOC to 80% SOC, the SOC change calculating unit 130 may calculate the SOC change amount as 50% and calculate the SOC change region as the SOC 30% to 80% region.

For convenience of explanation, in the embodiment of FIG. 11, it is shown that the C-rate calculating step (S200) and the SOC change calculating step (S300) are performed after the SOH estimating step (S100), but it should be noted that the order of performing the SOH estimating step (S100), the C-rate calculating step (S200) and the SOC change calculating step (S300) is not limited to the embodiment of FIG. 11. For example, the SOH estimating step (S100), the C-rate calculating step (S200) and the SOC change calculating step (S300) may be independently performed, respectively.

The weight calculating step (S400) is a step of calculating a weight based on at least one of a C-rate factor based on the charging and discharging C-rate, a SOC region factor according to the comparison result between the SOC change region and a preset criterion SOC region, a SOC change amount factor based on the SOC change amount, and a temperature factor based on the measured temperature of the battery, and may be performed by the weight calculating unit 140.

For example, the weight calculating unit 140 may calculate the C-rate factor for the charging and discharging C-rate calculated based on the C-rate factor table. Also, the weight calculating unit 140 may calculate the SOC region factor for the SOC change region based on the SOC region factor table. Also, the weight calculating unit 140 may calculate the SOC change amount factor for the SOC change amount based on the SOC change amount factor table. Also, the weight calculating unit 140 may calculate the temperature factor for the temperature of the battery based on the temperature factor table. In addition, the weight calculating unit 140 may calculate the weight by multiplying the calculated C-rate factor, the calculated SOC region factor, the calculated SOC change amount factor, and the calculated temperature factor.

The SOH correcting step (S500) is a step of correcting the first SOH according to the calculated weight and a preset second SOH, and may be performed by the SOH correcting unit 150.

For example, the SOH correcting unit 150 may correct the first SOH by adding a value obtained by multiplying the first SOH by a weight (α) and a value obtained by multiplying the second SOH by a complement (1−α) of the weight.

The battery SOH estimating method according to an embodiment of the present disclosure has an advantage of more accurately estimating SOH of the battery by considering various factors such as C-rate, SOC change region, SOC change amount, and temperature.

In addition, the battery SOH estimating method has an advantage of improving the SOH estimation accuracy by recursively estimating the SOH of the battery in the present cycle by considering the SOH of the battery estimated in the previous cycle and the weight calculated in the present cycle as the charging and discharging cycle of the battery progresses.

The embodiments of the present disclosure described above may not be implemented only through an apparatus and method, but may be implemented through a program that realizes a function corresponding to the configuration of the embodiments of the present disclosure or a recording medium on which the program is recorded. The program or recording medium may be easily implemented by those skilled in the art from the above description of the embodiments.

The present disclosure has been described in detail. However, it should be understood that the detailed description and specific examples, while indicating preferred embodiments of the disclosure, are given by way of illustration only, since various changes and modifications within the scope of the disclosure will become apparent to those skilled in the art from this detailed description.

In addition, since the present disclosure described above can be substituted, modified and changed in various ways by those skilled in the art without departing from the technical idea of the present disclosure, the present disclosure is not limited by the embodiments described above and the accompanying drawings, and all or some of the embodiments may be selectively combined to enable various modifications.

### EXPLANATION OF REFERENCE SIGNS

10: battery pack
11: battery
12: measuring unit
13: current measuring unit
100: battery SOH estimating apparatus
110: SOH estimating unit
120: C-rate calculating unit
130: SOC change calculating unit
140: weight calculating unit
150: SOH correcting unit
160: storage unit

1. A battery state of health (SOH) estimating apparatus, comprising:
a SOH estimator configured to estimate a first SOH of a battery based on battery information including at least one of voltage, current, and temperature of the battery;
a C-rate calculator configured to calculate a charging and discharging C-rate for the battery based on the battery information;
a state of charge (SOC) change calculator configured to calculate a SOC change region and a SOC change amount of the battery based on the battery information;
a weight calculator configured to calculate a weight based on at least one of a C-rate factor based on the charging and discharging C-rate, a SOC region factor according to a comparison between the SOC change region and a preset criterion SOC region, a SOC change amount factor based on the SOC change amount, and a temperature factor based on the temperature of the battery; and
a SOH corrector configured to correct the estimated first SOH according to the calculated weight and a preset second SOH.

2. The battery SOH estimating apparatus according to claim 1,
wherein the weight calculator is further configured to calculate the C-rate factor corresponding to the calculated charging and discharging C-rate based on a C-rate factor table preset to represent a corresponding relationship between the charging and discharging C-rate and the C-rate factor.

3. The battery SOH estimating apparatus according to claim 1,
wherein the weight calculator is further configured to calculate the C-rate factor corresponding to the calculated C-rate and the temperature based on a C-rate factor table preset to represent the C-rate factor according to the temperature of the battery and the charging and discharging C-rate.

4. The battery SOH estimating apparatus according to claim 3,
wherein the C-rate factor is configured to be proportional to the temperature and the charging and discharging C-rate.

5. The battery SOH estimating apparatus according to claim 1,
wherein the weight calculator is further configured to calculate the SOC region factor depending on whether at least a part of the SOC change region belongs to the preset criterion SOC region.

6. The battery SOH estimating apparatus according to claim 5,
wherein the preset criterion SOC region is among a plurality of preset criterion SOC regions, and
wherein the weight calculator is further configured to calculate a number of preset criterion SOC regions that include at least a part of the SOC change region among the plurality of preset criterion SOC regions, and to calculate the SOC region factor corresponding to the calculated number of preset criterion SOC regions based on a preset SOC region factor table.

7. The battery SOH estimating apparatus according to claim 1,
wherein the weight calculator is further configured to calculate the SOC change amount factor corresponding to the calculated SOC change amount based on a preset SOC change amount factor table.

8. The battery SOH estimating apparatus according to claim 1,
wherein the weight calculator is further configured to calculate the temperature factor corresponding to the temperature of the battery based on a preset temperature factor table.

9. The battery SOH estimating apparatus according to claim 1,
wherein the weight calculator is further configured to calculate the weight by multiplying the C-rate factor, the SOC region factor, the SOC change amount factor, and the temperature factor.

10. The battery SOH estimating apparatus according to claim 1,
wherein the SOH estimator is further configured to estimate the first SOH in a present cycle based on the battery information in the present cycle, and
wherein the SOH corrector is further configured to correct the estimated first SOH according to the calculated weight and the preset second SOH preset prior to the present cycle.

11. The battery SOH estimating apparatus according to claim 10,
wherein the preset second SOH is the estimated first SOH corrected in a cycle prior to the present cycle.

12. The battery SOH estimating apparatus according to claim 10,
wherein the SOH corrector is further configured to correct the estimated first SOH using the following equation:
$$S O {H}_{MOD} = ( S O {H}_{1} \times α ) + ( S O {H}_{2} \times ( 1 - α ) ) ,$$
where SOH_{MOD} is the corrected first SOH, SOH₁ is the estimated first SOH, SOH₂ is the preset second SOH, and α is the calculated weight that is greater or equal to 0 and less than or equal to 1.

13. A battery pack, comprising the battery SOH estimating apparatus according to claim 1.

14. A vehicle, comprising the battery SOH estimating apparatus according to claim 1.

15. A battery state of health (SOH) estimating method, comprising:
estimating a first SOH of a battery based on battery information including at least one of voltage, current, and temperature of the battery;
calculating a charging and discharging C-rate for the battery based on the battery information;
calculating a state of charge (SOC) change region and a SOC change amount of the battery based on the battery information;
calculating a weight based on at least one of a C-rate factor based on the charging and discharging C-rate, a SOC region factor according to a comparison between the SOC change region and a preset criterion SOC region, a SOC change amount factor based on the SOC change amount, and a temperature factor based on the temperature of the battery; and
correcting the estimated first SOH according to the calculated weight and a preset second SOH.
